(19) United States
(12) Patent Application Publication
(10) Pub. No.: US 2012/0126387 A1
(43) Pub. Date: May 24, 2012

(54) ENHANCED HEAT SPREADER FOR USE IN AN ELECTRONIC DEVICE AND METHOD OF MANUFACTURING THE SAME

(75) Inventors: Clifford R. Fishley, San Jose, CA (US); Abiola Awujoola, Pleasanton, CA (US)

(73) Assignee: LSI Corporation, Milpitas, CA (US)

(21) Appl. No.: 12/953,669

(22) Filed: Nov. 24, 2010

(51) Int. Cl. H01L 23/367; H01L 21/50

(52) U.S. Cl. 257/690; 438/122; 257/E23.103; 257/E21.499

(57) ABSTRACT

An electronic device includes an integrated circuit (IC) die attached to a substrate, and electrical conductors connecting the IC die to the substrate. The electronic device also includes a heat spreader located over the IC die and having a concaved portion located over the IC die along with a lateral portion extending from the concaved portion. The lateral portion has a surface area greater than a surface area of the concaved portion. A support member is further included that extends from the lateral portion to and contacts the substrate. An encapsulant covers the support member leaving the lateral and concaved portions exposed on outer sides thereof. In another aspect, a method of manufacturing an electronic device is also included.

### TECHNICAL FIELD

The present disclosure is directed, in general, to an integrated circuit and, more specifically, to an electronic device and a method of manufacturing an electronic device.

### BACKGROUND

Heat extraction from electronic devices remains an essential aspect of electronic system design. Increasing integration density has resulted in a steadily increasing power density (i.e., a quantity of power dissipated per unit area) for electronic devices. For example, factors such as shrinking dimensions of interconnect traces generally lead to greater interaction sensitivity. High temperature applications often provide effects, such as temperature-activated electromigration that are becoming more problematical along with the related costs of mitigating them. These factors have resulted in increasing attention to heat-related system design issues on the part of electronic device and system manufacturers. Therefore, enhanced heat management approaches that provide lower implementation times and costs would prove beneficial in the art.

### SUMMARY

Embodiments of the present disclosure provide an electronic device and a method of manufacturing an electronic device. In one embodiment, the electronic device includes an integrated circuit (IC) die attached to a substrate, and electrical conductors connecting the IC die to the substrate. The electronic device also includes a heat spreader located over the IC die and having a concaved portion located over the IC die and a lateral portion extending from the concaved portion, the lateral portion having a surface area greater than a surface area of the concaved portion and further including a support member extending from the lateral portion to and contacting the substrate. The electronic device further includes an encapsulant covering the support member leaving the lateral and concaved portions exposed on outer sides thereof.

In another aspect, the present disclosure includes the method of manufacturing an electronic device attaching an integrated circuit (IC) die to a substrate and connecting electrical conductors from the IC die to the substrate. The method also includes locating a heat spreader over the IC die and having a concaved portion located over the IC die and a lateral portion extending from the concaved portion, the lateral portion having a surface area greater than a surface area of the concaved portion and further including a support member extending from the lateral portion to and contacting the substrate. The method further includes covering the support member with an encapsulant leaving the lateral and concaved portions exposed on outer sides thereof.

The foregoing has outlined preferred and alternative features of the present disclosure so that those skilled in the art may better understand the detailed description of the disclosure that follows. Additional features of the disclosure will be described hereinafter that form the subject of the claims of the disclosure. Those skilled in the art will appreciate that they can readily use the disclosed conception and specific embodiment as a basis for designing or modifying other structures for carrying out the same purposes of the present disclosure.

### BRIEF DESCRIPTION OF THE DRAWINGS

For a more complete understanding of the present disclosure, reference is now made to the following descriptions taken in conjunction with the accompanying drawings, in which:

FIG. 1 illustrates a cross sectional view of an integrated circuit (IC) package containing an embodiment of a heat spreader constructed according to the principles of the present disclosure;

FIG. 2 illustrates a top view of an embodiment of the heat spreader shown in the cross sectional view of the IC package of FIG. 1;

FIG. 3 illustrates a cross sectional view of an IC package containing another embodiment of a heat spreader as provided by the current disclosure;

FIG. 4 illustrates a cross sectional view of an IC package including an embodiment of a heat spreader incorporating a heat sink as provided by the current disclosure;

FIG. 5 illustrates a cross sectional view of an IC package including another embodiment of a heat spreader and a heat sink as provided by the current disclosure;

FIG. 6 illustrates a cross sectional view of an IC package including yet another embodiment of a heat spreader and a heat sink as provided by the current disclosure;

FIG. 7 illustrates a cross sectional view of an IC package including still another embodiment of a heat spreader and a heat sink as provided by the current disclosure; and

FIG. 8 illustrates a flowchart of an embodiment of a method of manufacturing an electronic device carried out according to the principles of the present disclosure.

### DETAILED DESCRIPTION

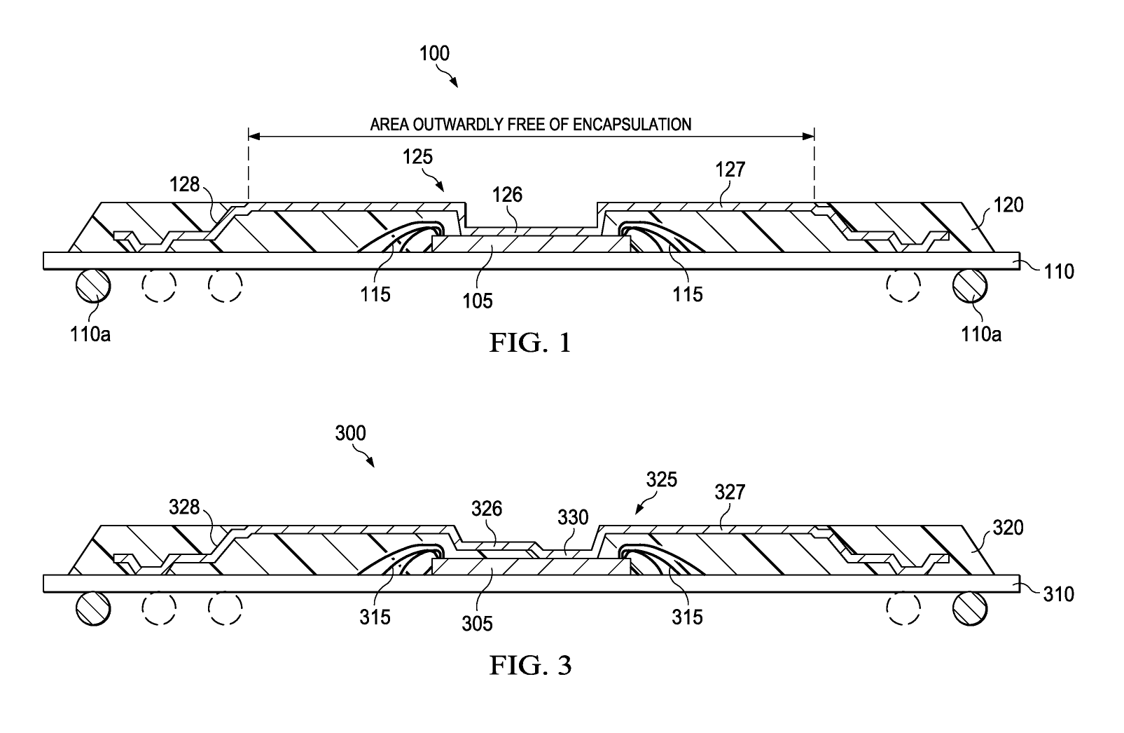

FIG. 1 illustrates a cross sectional view of an integrated circuit (IC) package, generally designated 100, containing an embodiment of a heat spreader constructed according to the principles of the present disclosure. The IC package 100 is generally representative of a plastic molded ball grid array (BGA) package that includes an IC die 105, a substrate 110, electrical conductors 115, an encapsulant 120 and a heat spreader 125.

The IC die 105 is attached to the substrate 110 wherein the electrical conductors 115 are employed to electrically connect the IC die 105 to the substrate 110. A collection of solder balls (wherein a solder ball 110a is typical) is also connected to the substrate 110 to provide outside connections of the IC die 105 for the plastic molded BGA package. The encapsulant 120 provides encapsulation of the IC die 105, the electrical conductors 115 and a portion of the heat spreader 125 on the substrate 110.

The heat spreader 125 is located over the IC die 105 and includes a concaved portion 126 located over the IC die 105. As seen in the embodiment of FIG. 1, the concaved portion 126 extends toward the IC die 105. The heat spreader 125 also includes a lateral portion 127 extending from the concaved portion 126 wherein the lateral portion 127 has a surface area greater than a surface area of the concaved portion 126. In the illustrated embodiment, the lateral portion 127 is planar. However, in other embodiments, the surface of the lateral portion 127 may be non-planar and may be extending away from the concaved portion 126 at an angle. The heat spreader 125 further includes a support member 128 extending from the lateral portion 127 to and contacting the substrate 110, to thereby support the weight of the heat spreader 125. The encapsulant 120 covers the support member 128 while leaving the concaved and lateral portions 126, 127 exposed on their outer sides (i.e., upper sides in this view, as noted).

Generally, the concaved portion 126 is depressed to reduce the distance from the IC die 105 to the heat spreader 125 thereby reducing the thickness of the encapsulant 120 that has a higher thermal resistance. This modification lowers the overall thermal resistance of the IC package 100. Additionally, the concaved portion 126 may be offered in multiple sizes to match various sizes of the IC die 105. Several embodiments for application of an external heat sink are discussed below. This feature allows balancing cost considerations against needed thermal performance requirements without change to the assembled IC package 100.

In certain embodiments, such as the one shown in FIG. 1, the concaved portion 126 may be in direct contact with the IC die 105. However, in other embodiments, the concaved portion 126 may be in close proximity to the IC die 105 such that the concaved portion 126 is in thermal contact with the IC die, such that heat is efficiently transferred from the IC die 105 to the concaved portion 126. Thus, the term “contact” as used herein with regard to the concaved portion 126 and the IC die 105, includes those instances where the concaved portion 126 is in direct contact with the IC die 105 or in thermal contact with the IC die 105.

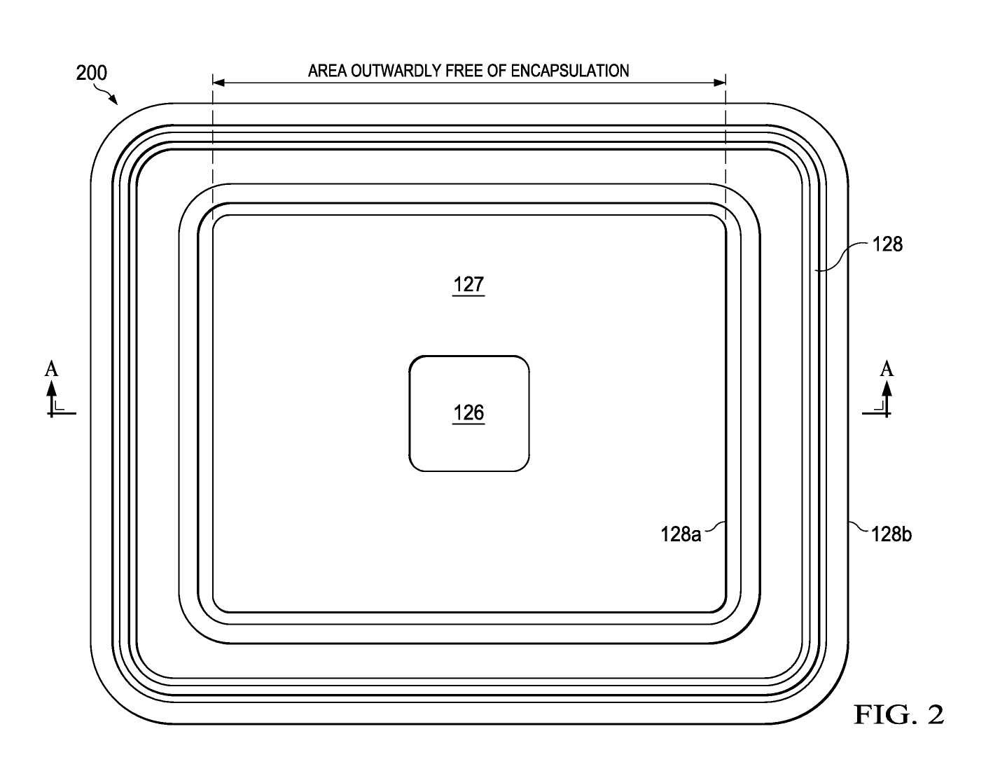

FIG. 2 illustrates a top view of an embodiment of the heat spreader 125, generally designated 200, shown in the cross sectional view of the IC package 100. The heat spreader 125 of FIG. 1 is representative of the section AA shown in FIG. 2. As shown, the surface area of the lateral portion 127 is greater than a surface area of the concaved portion 126. This is advantageous and an improvement over conventional heat spreaders in that this design provides a much larger surface area for more efficient heat transfer. The combined surface areas of the concaved and lateral portions 126, 127 are free of encapsulation in the plastic molded BGA package 100, such that a heat sink can be in thermal contact with the heat spreader 125. The support member 128 is encapsulated from an inner perimeter 128a to an outer perimeter 128b. The heat spreader 125 may typically be formed of any metal having a high thermal conductivity coefficient, such as copper, a copper compound, aluminum, gold, silver, platinum, etc. or similar metals as deemed appropriate for an application.

FIG. 3 illustrates a cross sectional view of an IC package, generally designated 300, containing another embodiment of a heat spreader as provided by the current disclosure. The IC package 300 is generally representative of another plastic molded BGA package that includes an IC die 305, a substrate 310, electrical conductors 315, an encapsulant 320 and a heat spreader 325.

The heat spreader 325 includes a concaved portion 326 located over the IC die 305, a lateral portion 327 and a support member 328. An encapsulant 320 covers the support member 328 while leaving the concaved and lateral portions 326, 327 exposed on their outer sides, as before. In this embodiment, the concaved portion 326 includes a secondary concaved portion 330 that is typically located over a “hot spot” in the IC die 305. The hot spot is a relatively higher power dissipation area of the IC die 305. In the illustrated embodiment, the secondary concaved portion 330 directly contacts the IC die 305 in the area of the hot spot. A remaining part of the concaved portion 326 does not directly contact the IC die 305, as shown. The secondary concaved portion 330 allows an enhanced thermal efficiency for the heat spreader 325 and the IC die 305.

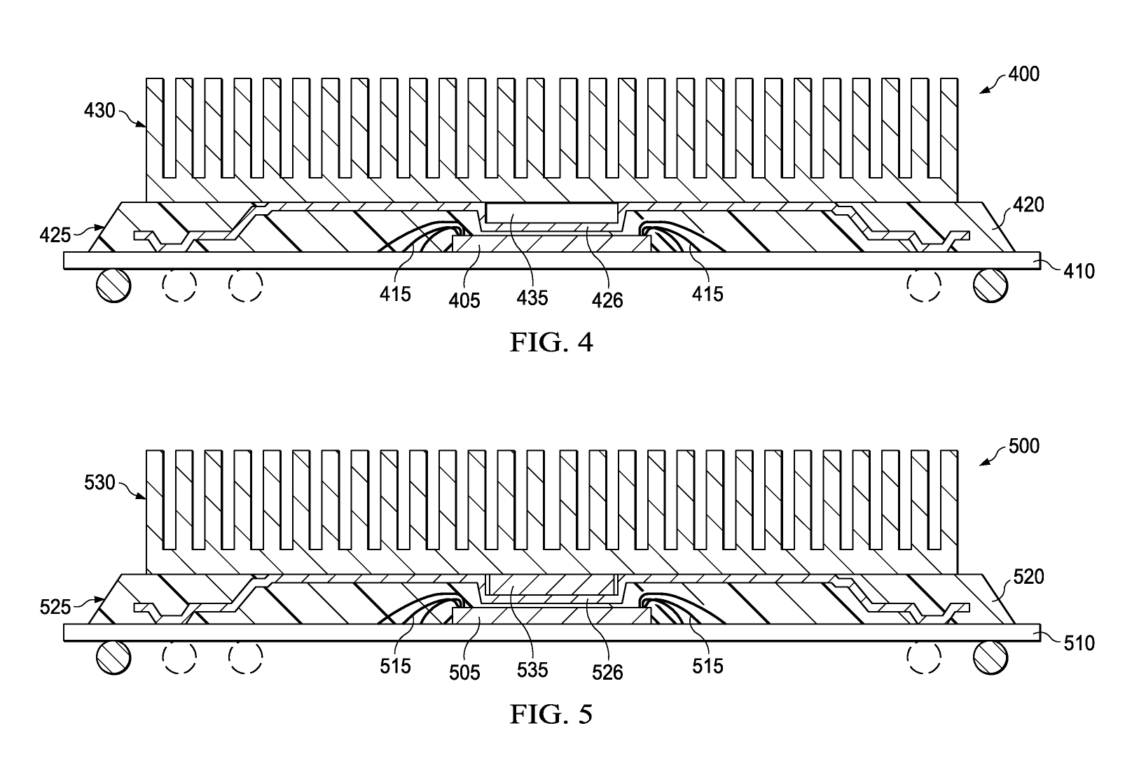

FIG. 4 illustrates a cross sectional view of an IC package, generally designated 400, including an embodiment of a heat spreader incorporating a heat sink as provided by the current disclosure. The IC package 400 is generally representative of another plastic molded BGA package that includes an IC die 405, a substrate 410, electrical conductors 415, an encapsulant 420, a heat spreader 425 and a heat sink 430.

In this embodiment, the heat spreader 425 includes a concaved portion 426 that is located over the IC die 405, and as discussed earlier, the concaved portion 426 may be in direct contact with the IC die 405, be in close proximity to the IC die 405, or a secondary concaved portion of the concaved portion may be in direct contact with or be in close proximity to the IC die 405. The heat sink 430 is located over the heat spreader 425 such that a space 435 is located between the heat sink 430 and the concaved portion 426. The heat sink 430 may also be formed of the same thermally conductive materials, as discussed earlier.

The term “contact” as used herein with regard to a heat sink and heat spreader, means that the heat sink may be in direct contact with the heat spreader, or alternatively that the heat sink may be in thermal contact with the heat spreader (e.g., one or more material thermal conductive layers may interpose the heat sink and heat spreader).

FIG. 5 illustrates a cross sectional view of an IC package, generally designated 500, including another embodiment of a heat spreader employing a heat sink as provided by the current disclosure. The IC package 500 is generally representative of another plastic molded BGA package that includes an IC die 505, a substrate 510, electrical conductors 515, an encapsulant 520, a heat spreader 525 and a heat sink 530.

In this embodiment, the heat spreader 525 includes a concaved portion 526 that is located over the IC die 505, as discussed earlier with respect to other embodiments. The heat sink 530 is located over and in thermal contact with the heat spreader 525, as before. However, a thermal conductive heat plug 535 is located in the space 435 of FIG. 4 that directly contacts the concaved portion 526 and the heat sink 530. The thermal conductive heat plug 535 may include a copper compound or consist of the metal copper entirely. Of course, other metallic compounds or metals, such as those discussed above may be employed as deemed appropriate.

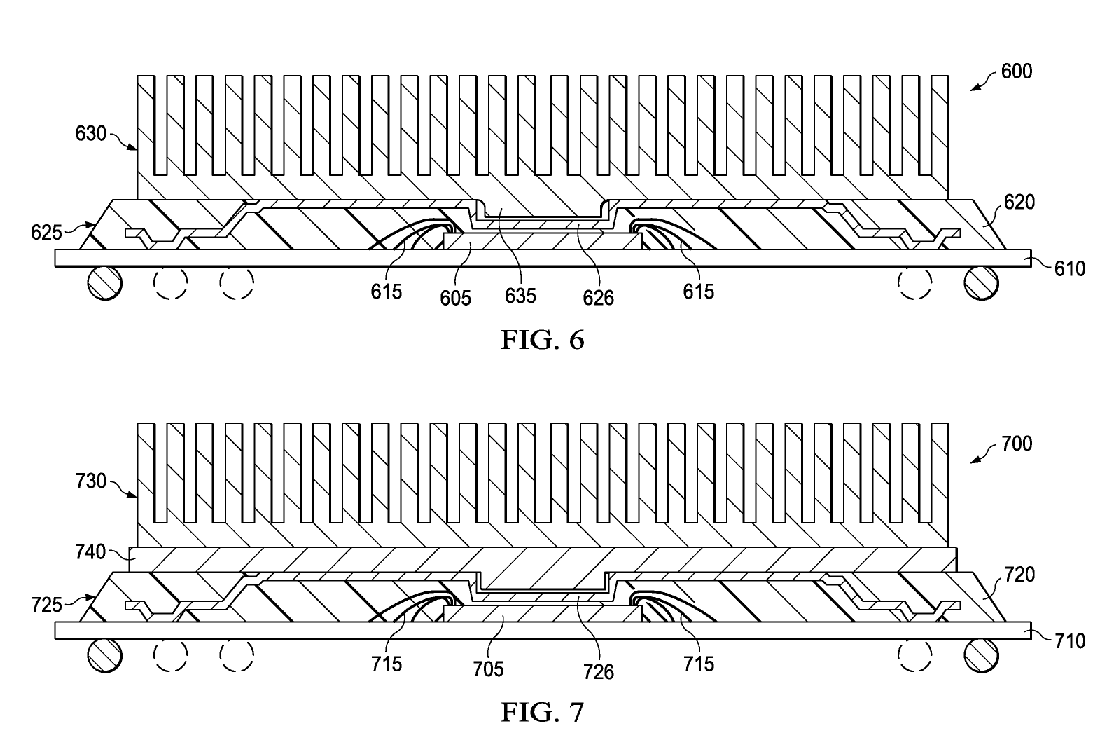

FIG. 6 illustrates a cross sectional view of an IC package, generally designated 600, including yet another embodiment of a heat spreader with a heat sink as provided by the current disclosure. The IC package 600 is generally representative of another plastic molded BGA package that includes an IC die 605, a substrate 610, electrical conductors 615, an encapsulant 620, a heat spreader 625 and a heat sink 630.

In this embodiment, the heat spreader 625 includes a concaved portion 626 that is located over the IC die 605, as discussed earlier regarding other embodiments. The heat sink 630 is located over and in thermal contact with the heat spreader 625, as before. However, a protrusion 635 of the heat sink 630 extends into the space 435 of FIG. 4 such as to directly contact the concaved portion 626.

The protrusion 635 may be formed in multiple ways including being machined as part of the heat sink 630 or attached separately by adhesives, fasteners or press fitting to the heat sink 630. The protrusion 635 may also be employed for automated heat sink centering during assembly of the IC package 600. The protrusion 635 represents an advantageous embodiment in that the protrusion 635 allows direct contact of the heat sink 630 with the concaved portion 626 of the heat spreader 625.

FIG. 7 illustrates a cross sectional view of an IC package, generally designated 700, including still another embodiment of a heat spreader and a heat sink as provided by the current disclosure. The IC package 700 is generally representative of another plastic molded BGA package that includes an IC die 705, a substrate 710, electrical conductors 715, an encapsulant 720, a heat spreader 725 and a heat sink 730.

In this embodiment, the heat spreader 725 includes a concaved portion 726 that is in thermal contact with the IC die 705, as discussed earlier regarding other embodiments. The heat sink 730 is located over and in thermal contact with the heat spreader 725. However, in this embodiment, a thermal conductive material 740 is located between and directly contacts the heat sink 730 and the heat spreader 725. As shown, a portion of the thermal conductive material 740 extends into the space 435 of FIG. 4.

Generally, the thermal conductive material 740 includes a metal and in this embodiment, the metal is an alloy of copper. Of course, other embodiments of a thermal conductive material may include different metals or combinations of metal compounds, as well, similar to those discussed above. Additionally, another embodiment of a thermal conductive material may not include a portion that extends into the space 435 of FIG. 4, but leaves the space 435 vacant.

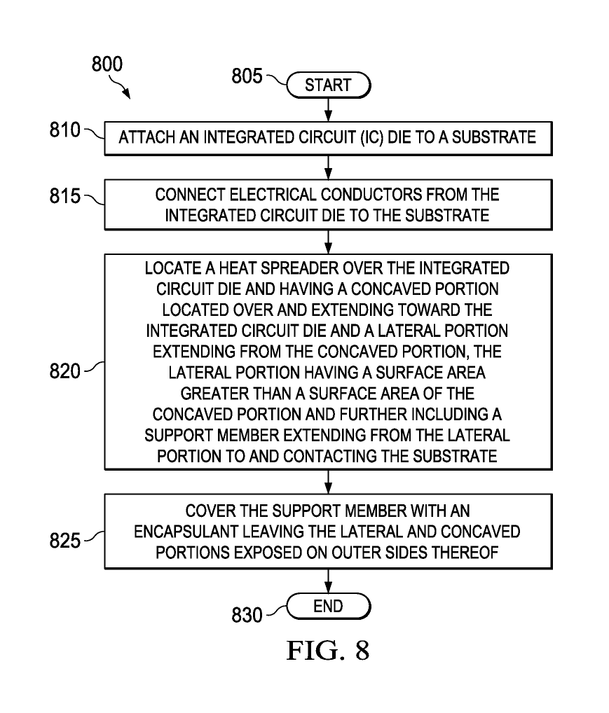

FIG. 8 illustrates a flowchart of an embodiment of a method of manufacturing an electronic device, generally designated 800, carried out according to the principles of the present disclosure. The method 800 starts in a step 805. Then, in a step 810, an integrated circuit (IC) die is attached to a substrate, and in a step 815, electrical conductors are connected from the IC die to the substrate.

In a step 820, a heat spreader is located over the IC die and includes a concaved portion located over the IC die. The heat spreader also includes a lateral portion extending from the concaved portion, wherein the lateral portion has a surface area greater than a surface area of the concaved portion. The heat spreader further includes a support member extending from the lateral portion to and contacting the substrate. In a step 825, the support member is covered with an encapsulant leaving the lateral and concaved portions exposed on outer sides thereof.

In one embodiment, the heat spreader is incorporated into a plastic molded ball grid array (BGA) package. In another embodiment, locating the heat spreader includes the concaved portion contacting the IC die. In yet another embodiment, the heat spreader includes a secondary concaved portion located in the concaved portion, wherein the secondary concaved portion contacts the IC die.

In still another embodiment, a heat sink is located over and in contact with the heat spreader thereby providing a space located between the heat sink and the concaved portion. In one application, a thermal conductive heat plug is located in the space between and contacts the heat sink and the concaved portion. In another application, the heat sink includes a protrusion that extends into the space between the heat sink and the concaved portion. In yet another application, a thermal conductive material is located between the heat sink and the heat spreader with a portion of the thermal conductive material extending into the space between the heat sink and the concaved portion. Correspondingly, the thermal conductive material may consist of a metal, for example, the metal copper or a metallic compound. The method 800 ends in a step 830.

While the method disclosed herein has been described and shown with reference to particular steps performed in a particular order, it will be understood that these steps may be combined, subdivided, or reordered to form an equivalent method without departing from the teachings of the present disclosure. Accordingly, unless specifically indicated herein, the order or the grouping of the steps is not a limitation of the present disclosure.

Those skilled in the art to which the disclosure relates will appreciate that other and further additions, deletions, substitutions and modifications may be made to the described example embodiments without departing from the disclosure.

What is claimed is:

1. An electronic device, comprising:
an integrated circuit (IC) die attached to a substrate;
electrical conductors connecting the IC die to the substrate;
a heat spreader located over the IC die and having a concaved portion located over the IC die and a lateral portion extending from the concaved portion, the lateral portion having a surface area greater than a surface area of the concaved portion and further including a support member extending from the lateral portion to and contacting the substrate; and
an encapsulant covering the support member leaving the lateral and concaved portions exposed on outer sides thereof.

2. The electronic device as recited in claim 1 wherein the heat spreader is incorporated into a plastic molded ball grid array (BGA) package.

3. The electronic device as recited in claim 1 further comprising a heat sink located over and in thermal contact with the heat spreader to provide a space located between the heat sink and the concaved portion.

4. The electronic device as recited in claim 3 wherein a thermal conductive heat plug is located in the space and contacts the concaved portion and the heat sink.

5. The electronic device as recited in claim 3 wherein the heat sink includes a protrusion that extends into the space.

6. The electronic device as recited in claim 3 wherein a thermal conductive material is located between the heat sink and the heat spreader and a portion of which extends into the space.

7. The electronic device as recited in claim 3 wherein the heat sink directly contacts the heat spreader.

8. The electronic device as recited in claim 1 wherein the concaved portion contacts the IC die.

9. The electronic device as recited in claim 1 wherein the concaved portion includes a secondary concaved portion.

10. The electronic device as recited in claim 9 wherein the secondary concaved portion contacts the IC die.

11. A method of manufacturing an electronic device, comprising:
attaching an integrated circuit (IC) die to a substrate;
connecting electrical conductors from the IC die to the substrate;
locating a heat spreader over the IC die and having a concaved portion located over the IC die and a lateral portion extending from the concaved portion, the lateral portion having a surface area greater than a surface area of the concaved portion and further including a support member extending from the lateral portion to and contacting the substrate; and
covering the support member with an encapsulant leaving the lateral and concaved portions exposed on outer sides thereof.

12. The method as recited in claim 11 wherein locating the heat spreader includes incorporating the heat spreader into a plastic molded ball grid array (BGA) package.

13. The method as recited in claim 11 further comprising locating a heat sink over and in thermal contact with the heat spreader and providing a space located between the heat sink and the concaved portion.

14. The method as recited in claim 13 wherein locating the heat sink includes locating a thermal conductive heat plug in the space such that the thermal conductive heat plug contacts the concaved portion and the heat sink.

15. The method as recited in claim 13 wherein locating the heat sink includes extending a protrusion of the heat sink into the space.

16. The method as recited in claim 13 wherein locating the heat sink includes locating a thermal conductive material between the heat sink and the heat spreader with a portion of the thermal conductive material extending into the space.

17. The method as recited in claim 16 wherein locating the heat sink includes placing the heat sink in direct contact with the heat spreader.

18. The method as recited in claim 11 wherein locating the heat spreader includes the concaved portion contacting the IC die.

19. The method as recited in claim 11 wherein locating the heat spreader includes the concaved portion containing a secondary concaved portion.

20. The method as recited in claim 19 wherein locating the heat spreader includes the secondary concaved portion contacting the IC die.
